(19) United States
(12) Patent Application Publication
(10) Pub. No.: US 2002/0003272 A1
(43) Pub. Date: Jan. 10, 2002

(54) ULTRA SHORT CHANNEL LENGTH DICTATED BY THE WIDTH OF A SACRIFICIAL SIDEWALL SPACER

(76) Inventors: MARK I. GARDNER, CEDAR CREEK, TX (US); JON D. CHEEK, ROUND ROCK, TX (US)

Correspondence Address: KEVIN L DAFFER, CONLEY ROSE & TAYON, P O BOX 3267, HOUSTON, TX, 772533267

(21) Appl. No.: 09/034,632

(22) Filed: Mar. 4, 1998

(51) Int. Cl. H01L 21/336

(52) U.S. Cl. 257/412; 438/299

(57) ABSTRACT

An integrated circuit fabrication process is provided in which a transistor is formed which has an ultra short channel length dictated by the width of a sacrificial sidewall spacer. In one embodiment, the sacrificial sidewall spacer is formed upon the sidewall surface of an upper portion of a polysilicon layer. The sidewall surface is formed by etching partially through an unmasked portion of the polysilicon layer. The lateral thickness of the sidewall spacer is dictated by the duration of an anisotropic etch of a spacer material used to form the sidewall spacer. Portions of the polysilicon layer not covered by the sidewall spacer are etched to form a gate conductor of an ensuing transistor. Subsequent LDD and source/drain implants are aligned to the opposed sidewall surfaces of the gate conductor and to sidewall spacers formed upon the gate conductor, respectively. Therefore, the channel length of the transistor is the same as the gate width, and hence the lateral thickness of the sacrificial sidewall spacer. In an alternate embodiment, the sacrificial sidewall spacer is formed upon the sidewall surface of an upper polysilicon layer. The upper polysilicon layer is spaced above a lower polysilicon layer by an etch stop layer. The sidewall surface is formed by etching an unmasked portion of the upper polysilicon layer to the etch stop layer. Portions of the lower polysilicon layer not covered by the sidewall spacer are removed to form a gate conductor.

### BACKGROUND OF THE INVENTION

1. Field of the Invention

This invention relates to integrated circuit fabrication and, more particularly, to forming a transistor having an ultra short channel length dictated by the width of a sacrificial sidewall spacer formed upon a sidewall surface of an etched polysilicon layer.

2. Description of the Related Art

Fabrication of a MOSFET device is well known. Generally speaking, MOSFETs are manufactured by placing an undoped polycrystalline silicon (“polysilicon”) material over a relatively thin gate oxide arranged above a semiconductor substrate. The polysilicon material and the gate oxide are patterned to form a gate conductor with source/drain regions (i.e., junctions) adjacent to and on opposite sides of the gate conductor within the substrate. The gate conductor and source/drain regions are then implanted with an impurity dopant. If the dopant species employed for forming the source/drain regions is n-type, then the resulting MOSFET is an NMOSFET (n-channel) transistor device. Conversely, if the source/drain dopant species is p-type, then the resulting MOSFET is a PMOSFET (p-channel) transistor device. Integrated circuits utilize either n-channel devices exclusively, p-channel devices exclusively, or a combination of both on a single monolithic substrate.

Because of the increased desire to build faster and more complex integrated circuits, it has become necessary to reduce the transistor threshold voltage, V_{T}. Several factors contribute to V_{T}, one of which is the effective channel length (“Leff”) of the transistor. The initial distance between the source-side junction and the drain-side junction of a transistor is often referred to as the physical channel length. However, after implantation and subsequent diffusion of the junctions, the actual distance between junctions becomes less than the physical channel length and is often referred to as the effective channel length. In VLSI designs, as the physical channel length decreases, so too must the Leff. Decreasing Leff reduces the distance between the depletion regions associated with the source and drain of a transistor. As a result, less gate charge is required to invert the channel of a transistor having a shorter Leff. Accordingly, reducing the physical channel length, and hence the Leff, can lead to a reduction in the threshold voltage of a transistor. Consequently, the switching speed of the logic gates of an integrated circuit employing transistors with reduced Leff is faster, allowing the integrated circuit to quickly transition between logic states (i.e., operate at high frequencies).

Unfortunately, minimizing the physical channel length of a transistor is somewhat limited by conventional techniques used to define the gate conductor of the transistor. As mentioned earlier, the gate conductor is typically formed from a polysilicon material. A technique known as lithography is used to pattern a photosensitive film (i.e., photoresist) above the polysilicon material. An optical image is transferred to the photoresist by projecting a form of radiation, typically ultraviolet light, through the transparent portions of a mask plate. The solubility of photoresist regions exposed to the radiation is altered by a photochemical reaction. The photoresist is washed with a solvent that preferentially removes resist areas of higher solubility. Those exposed portions of the polysilicon material not protected by photoresist are etched away, defining the geometric shape of the opposed sidewall surfaces of a polysilicon gate conductor.

The lateral width (i.e., the distance between opposed sidewall surfaces) of the gate conductor which dictates the physical channel length of a transistor is thus defined by the lateral width of an overlying photoresist layer. The minimum lateral dimension that can be achieved for a patterned photoresist layer is unfortunately limited by, inter alia, the resolution of the optical system (i.e., aligner or printer) used to project the image onto the photoresist. The term “resolution” describes the ability of an optical system to distinguish closely spaced objects. Diffraction effects may undesirably occur as the radiation passes through slit-like transparent regions of the mask plate, scattering the radiation and therefore adversely affecting the resolution of the optical system. As such, the features patterned from a masking plate may be skewed, enlarged, shortened, warped, or otherwise incorrectly printed onto the photoresist.

It would therefore be desirable to develop a transistor fabrication technique in which the channel length of the transistor is reduced to provide for high frequency operation of an integrated circuit employing the transistor. More specifically, a process is needed in which the channel length is no longer dictated by the resolution of a lithography optical aligner. The lateral width of a gate conductor which defines the channel length of a transistor must no longer be determined by an image printed onto photoresist. Otherwise, the image could be altered during optical lithography, resulting in the dimensions of the gate conductor being altered from design specifications. A process which avoids the limitations of lithographic exposure used for defining opposed sidewalls (i.e., boundaries) of conventional gate conductors would beneficially allow the channel length, and hence the Leff, of a transistor to be scaled to a smaller size. Minimizing the Leff of a transistor would advantageously increase the speed at which the logic gates of a transistor switch between its on and off states.

### SUMMARY OF THE INVENTION

The problems outlined above are in large part solved by the technique hereof for fabricating a transistor in which the channel length is controlled by the lateral thickness of a sacrificial sidewall spacer. The spacer is sacrificial in that it is removed from the semiconductor topography after it has served its purpose of masking the underlying polysilicon gate material. In an embodiment, the sidewall spacer is formed upon a sidewall surface of an upper portion of a polysilicon layer and above a select region of a lower portion of the polysilicon layer. The sidewall surface of the polysilicon layer is defined by etching an unmasked region of the polysilicon layer for a pre-defined period of time. The etch is preferably terminated after about ½ to ⅓ of the overall thickness of the unmasked region of the polysilicon layer has been removed. In an alternate embodiment, the sidewall spacer is formed upon a sidewall surface of an upper polysilicon layer which is spaced above a lower polysilicon layer by an etch stop layer. The etch stop layer is composed of a material dissimilar from polysilicon. An unmasked portion of the upper polysilicon layer is etched to the etch stop layer to define the sidewall surface using an etch technique which exhibits a high selectivity for polysilicon. Therefore, the presence of the etch stop layer underneath the upper polysilicon layer ensures that the etch step is terminated before substantial portions of the lower polysilicon layer can be removed.

In either embodiment, the sidewall spacer is formed by depositing a spacer material across the semiconductor topography comprising a sidewall surface of a partial or entire layer of polysilicon. The spacer material is anisotropically etched such that it is removed from horizontally oriented surfaces at a faster rate than from vertically oriented surfaces. The duration of the anisotropic etch is preferably terminated after the spacer material is removed from all horizontally oriented surfaces but before the spacer material is completely removed from the vertical sidewall surface. The lateral thickness of the resulting sidewall spacer which is retained upon the sidewall surface of the polysilicon layer is thus dictated by the duration of the anisotropic etch step. Accordingly, the lateral thickness and/or extents of the sidewall spacer may be reduced by decreasing the duration of the anisotropic etch step. The sidewall spacer is composed of a material dissimilar from polysilicon. Therefore, portions of the polysilicon layer not covered by the sidewall spacer may be selectively removed using an anisotropic etch which exhibits a high selectivity for polysilicon as compared to the spacer material. In this manner, a polysilicon gate conductor may be formed exclusively beneath the sidewall spacer.

The resulting gate conductor has a width which is substantially the same as the lateral thickness of the sidewall spacer. During subsequent implantation of dopants into exposed regions of a semiconductor substrate, the gate conductor serves as a mask to an underlying channel region of the semiconductor substrate. Therefore, the width of the gate conductor dictates the physical channel length of an ensuing transistor. Absent optical lithography to define the width of the gate conductor, the minimum size of the physical channel length is no longer sacrificed by the limited resolution of an optical system. As such, the lateral thickness of the sidewall spacer may be scaled down to minimize the physical channel length, and hence the Leff, of an ensuing transistor.

In one embodiment, the height of the gate conductor is dictated by both the thickness of the polysilicon layer deposited across a gate dielectric and by the thickness of the portion of the polysilicon layer that is removed to define the sidewall surface. Assuming that knowledge of the deposition rate and the etch rate of the polysilicon layer is known, the height of the gate conductor may be controlled by varying the duration of the deposition and etch steps. In another embodiment, the height of the gate conductor is dictated primarily by the thickness of a lower polysilicon layer deposited across a gate dielectric. An etch stop layer formed across the lower polysilicon layer serves to terminate the etching of an overlying upper polysilicon layer before substantial portions of the lower polysilicon layer can be removed. The etch stop layer advantageously eliminates the necessity of precisely controlling the etch duration to adjust the height of the gate conductor.

According to one embodiment, a polysilicon layer is deposited across a gate dielectric arranged upon a semiconductor substrate using chemical vapor deposition (“CVD”). A masking layer, preferably photoresist, is then patterned across a select portion of the polysilicon layer. An exposed portion of the polysilicon layer which is not protected by the sacrificial layer is then etched using, e.g., an dry, plasma etch, to a level spaced below the upper surface of the masked (or covered) portion of the polysilicon layer. The etch duration is terminated after approximately ⅓ to ½ of the thickness of the exposed portion has been removed. As a result of this etch step, a sidewall spacer is defined above a lower portion of the polysilicon layer and laterally adjacent the boundary of an upper portion of the polysilicon layer. The masking layer is then removed, and a spacer material which is substantially dissimilar from polysilicon (e.g., metal or nitride) is deposited across the polysilicon layer. The spacer material is anisotropically etched to form a sidewall spacer upon only the sidewall surface of the sacrificial layer. The etch duration is selected to last until only a pre-defined lateral thickness of the spacer material remains upon the sidewall surface. The sidewall spacer is thus formed above a select region of the polysilicon layer. Regions of the polysilicon layer not protected by an overlying sidewall spacer are then selectively removed using an etch technique which exhibits high selectivity for polysilicon relative to the sidewall spacer material. In this manner, a gate conductor is formed between a pair of opposed sidewall surfaces which are aligned directly below the opposed lateral surfaces of the sidewall spacer. As such, the width of the gate conductor is substantially equivalent to the lateral thickness of the sidewall spacer.

In an alternate embodiment, a lower polysilicon layer is CVD deposited across a gate dielectric arranged above a semiconductor substrate. An etch stop layer which is composed of a material dissimilar from polysilicon is then formed across the first polysilicon layer. The etch stop layer may, e.g., be a CVD deposited silicon dioxide (“oxide”) layer. An upper polysilicon layer is deposited across the etch stop layer. Subsequently, a masking or sacrificial layer, preferably photoresist, is patterned across a select portion of the upper polysilicon layer. An exposed portion of the upper polysilicon layer is then etched to the underlying etch stop layer using an etch technique which is highly selective to polysilicon as compared to the etch stop layer. In this manner a sidewall surface is defined for the upper polysilicon layer. After removing the sacrificial layer, a spacer material which is substantially dissimilar from the etch stop layer and from polysilicon is deposited across the etch stop layer and the upper polysilicon layer. The spacer material is anisotropically etched to form a sidewall spacer upon only the sidewall surface of the upper polysilicon layer. Portions of the etch stop layer and the lower polysilicon layer not arranged underneath the sidewall spacer are then sequentially etched to define a polysilicon gate conductor. The lateral width of the gate conductor is the same as the lateral thickness of the sidewall spacer.

Subsequent to either of the above embodiments, the sidewall spacer (and etch stop layer if present) may be selectively removed, and a lightly doped drain (“LDD”) implant which is self-aligned to the opposed sidewall surfaces of the gate conductor may be forwarded into the semiconductor substrate. The LDD implant forms LDD areas within the upper surface of the substrate. Dielectric spacers may then be formed upon the opposite sidewall surfaces of the gate conductor. A heavily doped source/drain implant which is self-aligned to the exposed lateral surfaces of the dielectric spacers is then forwarded into the substrate to form heavily doped source/drain regions. Since the S/D implant is performed at a higher dose than the LDD implant, the heavily doped source/drain regions dominate those portions of the LDD areas not arranged underneath the dielectric spacers. The channel length of the resulting transistor extends between the LDD areas, and is thus dictated by the width of the gate conductor.

### BRIEF DESCRIPTION OF THE DRAWINGS

Other objects and advantages of the invention will become apparent upon reading the following detailed description and upon reference to the accompanying drawings in which:

FIG. 1 is a cross-sectional view of a semiconductor topography according to one embodiment, wherein a gate dielectric is formed across a semiconductor substrate;

FIG. 2 is a cross-sectional view of the semiconductor topography, wherein a polysilicon layer is deposited across the gate dielectric, subsequent to the step in FIG. 1;

FIG. 3 is a cross-sectional view of the semiconductor topography, wherein a masking or sacrificial layer is patterned upon a portion of the polysilicon layer, subsequent to the step in FIG. 2;

FIG. 4 is a cross-sectional view of the semiconductor topography, wherein an exposed portion of the polysilicon layer is etched to a level spaced below the unexposed portion of the polysilicon layer to form a vertically extending sidewall surface separating the exposed and unexposed portions, subsequent to the step in FIG. 3;

FIG. 5 is a cross-sectional view of the semiconductor topography, wherein a sidewall spacer is formed exclusively upon, and extending a desired distance from, the sidewall surface of the polysilicon layer, subsequent to the step in FIG. 4;

FIG. 6 is a cross-sectional view of the semiconductor topography, wherein portions of the polysilicon layer not covered by the sidewall spacer are etched to the gate dielectric to define a gate conductor, subsequent to the step in FIG. 5;

FIG. 7 is a cross-sectional view of the semiconductor topography, wherein an LDD implant which is self-aligned to the opposed sidewall surfaces of the gate conductor is forwarded into the semiconductor substrate, subsequent to the step in FIG. 6;

FIG. 8 is a cross-sectional view of the semiconductor topography, wherein dielectric sidewall spacers are formed upon the opposed sidewall surfaces of the gate conductor, subsequent to the step in FIG. 7;

FIG. 9 is a cross-sectional view of the semiconductor topography, wherein a source/drain implant which is self-aligned to the exposed lateral surfaces of the sidewall spacers is forwarded into the semiconductor substrate, subsequent to the step in FIG. 8;

FIG. 10 is a cross-sectional view of a semiconductor topography according to another embodiment, wherein a gate dielectric is formed across a semiconductor substrate;

FIG. 11 is a cross-sectional view of the semiconductor topography, wherein a first polysilicon layer is formed across the gate dielectric, subsequent to the step in FIG. 10;

FIG. 12 is a cross-sectional view of the semiconductor topography, wherein an etch stop layer is formed across the first polysilicon layer, subsequent to the step in FIG. 11;

FIG. 13 is a cross-sectional view of the semiconductor topography, wherein a second polysilicon layer is deposited across the etch stop layer, subsequent to the step in FIG. 12;

FIG. 14 is a cross-sectional view of the semiconductor topography, wherein a masking or sacrificial layer is patterned upon a portion of the second polysilicon layer, subsequent to the step in FIG. 13;

FIG. 15 is a cross-sectional view of the semiconductor topography, wherein an exposed portion of the second polysilicon layer is etched to the etch stop layer to form a vertically extending sidewall surface separating the exposed and unexposed portions, subsequent to the step in FIG. 14;

FIG. 16 is a cross-sectional view of the semiconductor topography, wherein a sidewall spacer is formed exclusively upon, and extending a desired distance from, the sidewall surface of the second polysilicon layer, subsequent to the step in FIG. 15;

FIG. 17 is a cross-sectional view of the semiconductor topography, wherein the remaining portion of the second polysilicon layer is etched to the etch stop layer, subsequent to the step in FIG. 16;

FIG. 18 is a cross-sectional view of the semiconductor topography, wherein portions of the etch stop layer not covered by the sidewall spacer are etched to the first polysilicon layer, subsequent to the step in FIG. 17;

FIG. 19 is a cross-sectional view of the semiconductor topography, wherein portions of the first polysilicon layer not covered by the sidewall spacer are etched to the gate dielectric, subsequent to the step in FIG. 18;

FIG. 20 is a cross-sectional view of the semiconductor topography, wherein an LDD implant which is self-aligned to the opposed sidewall surfaces of the gate conductor is forwarded into the semiconductor substrate, subsequent to the step in FIG. 19;

FIG. 21 is a cross-sectional view of the semiconductor topography, wherein dielectric sidewall spacers are formed upon the opposed sidewall surfaces of the gate conductor, subsequent to the step in FIG. 20; and

FIG. 22 is a cross-sectional view of the semiconductor topography, wherein a source/drain implant which is self-aligned to the exposed lateral surfaces of the sidewall spacers is forwarded into the semiconductor substrate, subsequent to the step in FIG. 21.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE INVENTION

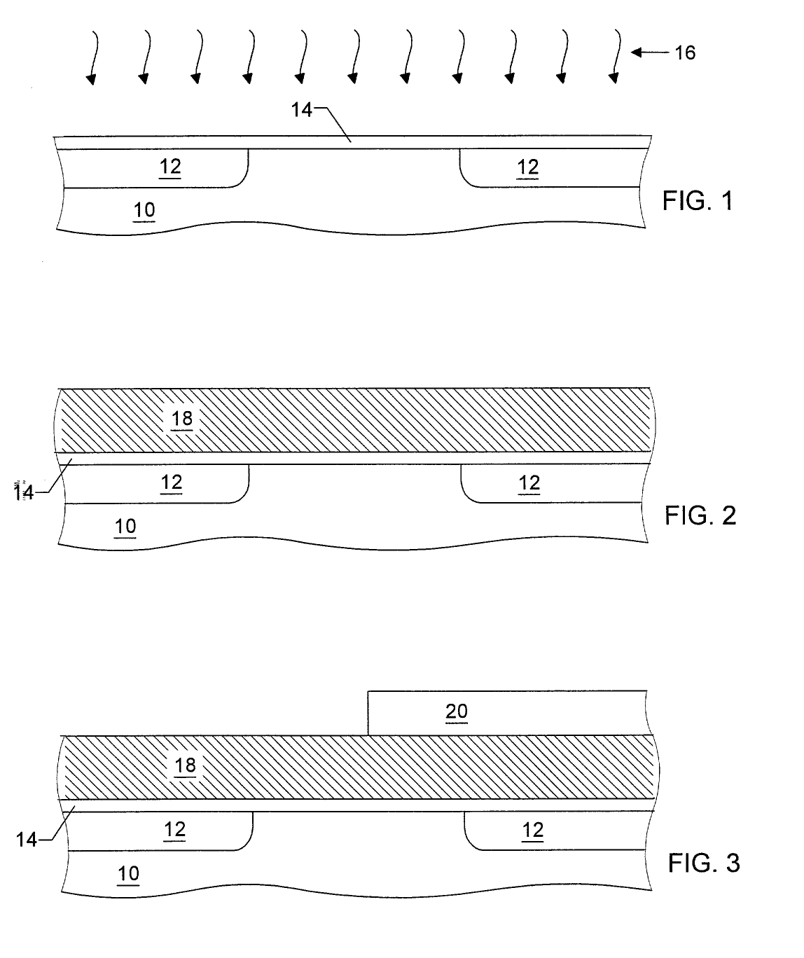

FIGS. 1-9 illustrate the formation of a transistor according to one embodiment of the present invention. Turning to FIG. 1, a single crystalline silicon substrate 10 is depicted upon which a gate dielectric 14 is formed. Substrate 10 is slightly doped with p-type or n-type dopant species. Trench isolation structures 12 are arranged within substrate 10 and serve to isolate an ensuing active area from other active areas within substrate 10. Trench isolation structure 12 may be replaced with a LOCOS structure in an alternate embodiment. In another embodiment, a well region containing dopants that are opposite in type to the dopants positioned in the bulk of substrate 10 may be formed in the ensuing active area. Gate dielectric 14 is preferably an oxide which is thermally grown upon substrate 10 by exposing the substrate to thermal radiation 16 in an oxygenbearing ambient. Gate dielectric 14 is not limited to thermally grown oxide and may be other materials, such as barium strontium titanate or cerium oxide.

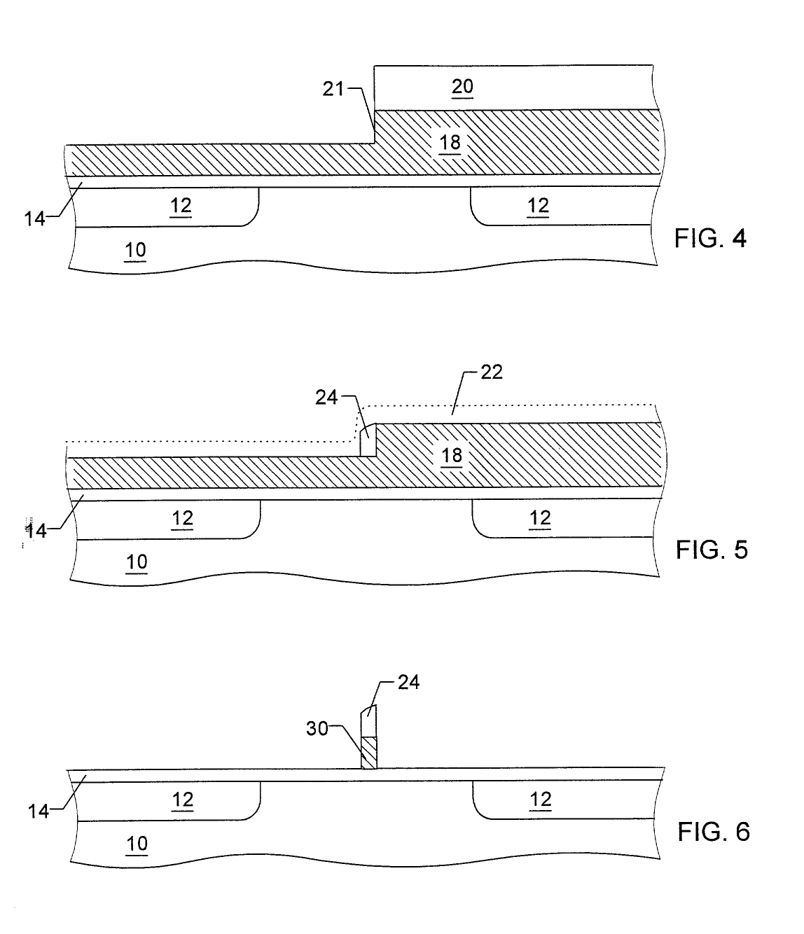

As shown in FIG. 2, a polysilicon layer 18 is CVD deposited from, e.g., a silane source, across gate dielectric 14. Polysilicon layer 18 may be doped with p-type or n-type dopants during or subsequent to the deposition to render the polysilicon layer conductive. FIG. 3 depicts the formation of a sacrificial layer 20 upon a select portion of polysilicon layer 18. Preferably, sacrificial layer 20 comprises photoresist which may be patterned using optical lithography. Sacrificial layer 20 may also be composed of a material other than photoresist, e.g., oxide, as long as the material is dissimilar from polysilicon. If sacrificial layer 20 is not photoresist, it may be formed using both lithography and an etch technique, e.g., a dry, plasma etch. As shown if FIG. 4, a portion of polysilicon layer 18 not covered by sacrificial layer 20 may be etched using, e.g., a dry, plasma etch. The etch duration is preferably selected to terminate after approximately ⅓ to ½ of the thickness of the exposed portion of polysilicon layer 18 is removed. As a result of etching polysilicon layer 18, a sidewall surface 21 is preferably formed about the periphery of an upper portion of the polysilicon layer, and serves to vertically demarcate the upper and lower portions.

Turning to FIG. 5, a sidewall spacer 24 is formed upon the sidewall surface of polysilicon layer 18 subsequent to stripping sacrificial layer 20 from polysilicon layer 18. Sidewall spacer 24 is formed by first depositing a spacer material across polysilicon layer 18. The spacer material is preferably composed of silicon dioxide, silicon nitride, or silicon oxynitride, but may be composed of any material dissimilar from polysilicon. The spacer material is then anisotropically etched such that a portion 22 of the spacer material is removed. The etch duration is chosen to terminate after only a pre-defined thickness of spacer material remains upon the sidewall surface of polysilicon layer 18. The resulting sidewall spacer 18 may have a thickness of, e.g., 50 to 200 Å. Turning to FIG. 6, an anisotropic etch which is highly selective to polysilicon relative to sidewall spacer 24 is performed. In this manner, portions of polysilicon layer 18 not covered by sidewall spacer 24 are selectively etched to define a gate conductor 30. The etch duration may be terminated before substantial portions of gate dielectric 14 are removed. The opposed sidewall surfaces of the resulting gate conductor 30 are aligned to the opposed lateral surfaces of sidewall spacer 24. As such, the lateral thickness of sidewall spacer 24 dictates the width of gate conductor 30. Therefore, the width of gate conductor 25 may be reduced to between 50 and 200 Å by controlling the duration of the anisotropic etch used to form sidewall spacer 24.

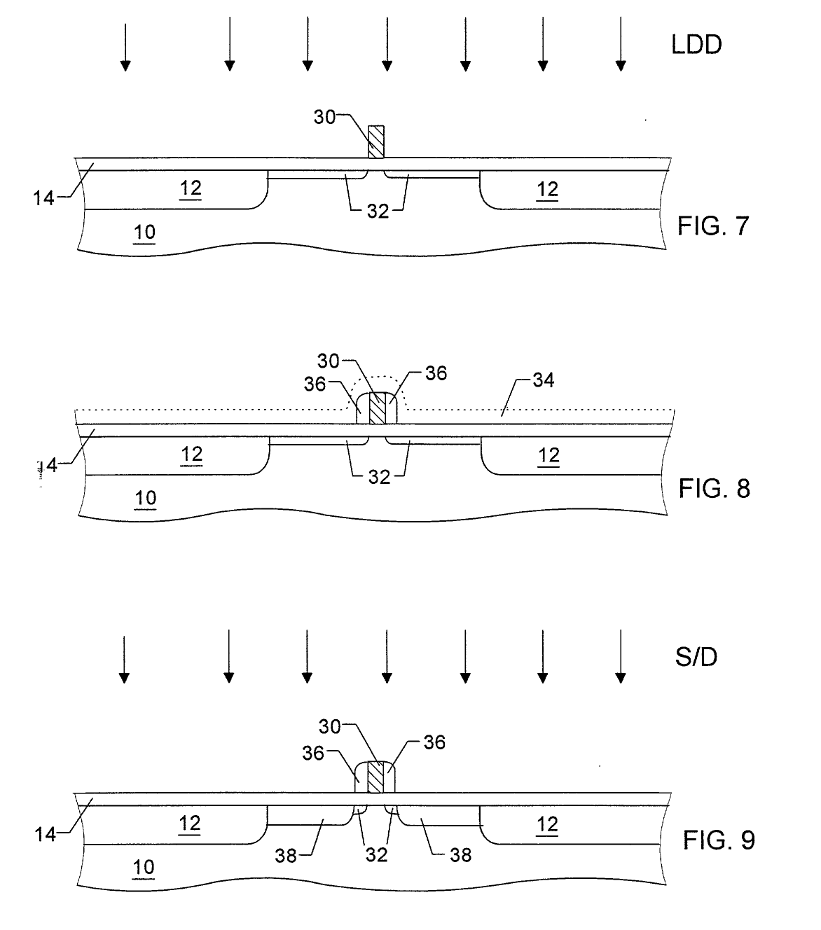

Turning to FIG. 7, sidewall spacer 24 may be removed before or after an LDD implant which is forwarded into semiconductor substrate 10. The LDD implant is self-aligned to the opposed sidewall surfaces of gate conductor 30, resulting in the formation of LDD areas 32 within substrate 10 laterally between gate conductor 30 and trench isolation structures 12. LDD areas 32 are arranged on opposite sides of a channel region residing directly below gate conductor 30. As shown in FIG. 9, sidewall spacers 36 are formed upon the opposed sidewall surfaces of gate conductor 30 by first depositing a dielectric material, e.g., silicon dioxide, silicon nitride, or silicon oxynitride, across the semiconductor topography. The dielectric material is then anisotropically etched to remove a portion 34 of the dielectric material while retaining sidewall spacers 36 upon the opposed sidewall surfaces of gate conductor 30.

Turning to FIG. 9, a source/drain (“S/D”) implant which is self-aligned to the exposed lateral surfaces of sidewall spacers 36 is then forwarded into substrate 10 to form source/drain regions 38. If a PMOSFET transistor is being fabricated, p-type species are implanted, and if an NMOSFET integrated circuit is being formed, n-type species are implanted. Some commonly used p-type dopants are boron or boron difluoride, and some commonly used n-type dopants are arsenic or phosphorus. The implanted dopant species may be opposite in type to the dopant species positioned within the bulk of substrate 10. Alternatively, if a well region exists within substrate 10 between isolation structures 12, the implanted dopant species may be opposite in type to the dopant species arranged within the well region, allowing for the formation of a CMOS circuit. The presence of gate dielectric 14 provides for adequate distribution of the implanted impurities. The concentration of dopant species is chosen to effectuate whatever threshold voltage is required to operate, within the design specification, the ensuing transistor. The source/drain implant is performed at a higher energy and dose than the LDD implant depicted in FIG. 8. The source/drain implant employs the same type of dopant species as the LDD implant. As such, source/drain regions 38 consume portions of the previous LDD areas 32. Thus, LDD areas 32 which are shallower and have a lower concentration of dopants than source/drain regions 36 become arranged exclusively underneath sidewalls spacers 36. The lateral width of each LDD area 32 is approximately equivalent to the lateral thickness of each sidewall spacer 36. Also, each source/drain region 38 is spaced from gate conductor 30 by a distance approximately equivalent to the lateral thickness of each sidewall spacer 36. The combination of LDD areas 32 and source/drain regions 38 form graded junctions on opposite sides of the channel region arranged below gate conductor 30.

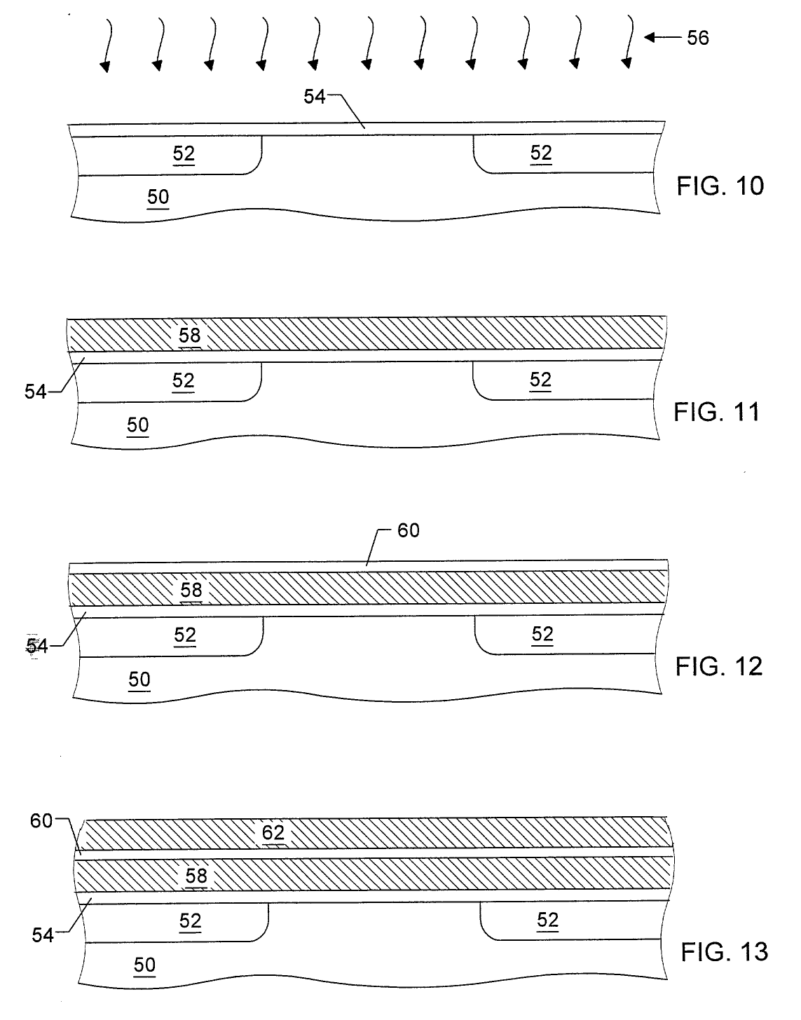

FIGS. 10-22 illustrate the formation of a transistor according to an alternate embodiment of the present invention. Many of the steps depicted in FIGS. 10-22 are similar to steps shown in FIGS. 1-9. FIG. 10 illustrates the formation of a gate dielectric 54 across a semiconductor substrate 50. Semiconductor substrate preferably comprises is lightly doped single crystalline silicon. Trench isolation structures 52 which may be composed of oxide are arranged a spaced distance apart within substrate 50. Gate dielectric 54 may be formed by exposing substrate 50 to thermal radiation 56 in an oxygen-bearing ambient. Thus, gate dielectric 54 may comprise a thermally grown oxide. As shown in FIG. 11, a first polysilicon layer 58 is CVD deposited across gate dielectric 54 from, e.g., a silane-bearing gas. Thereafter, as depicted in FIG. 12, an etch stop layer 60 may be formed across first polysilicon layer 58. Etch stop layer 60 is preferably formed by CVD depositing an oxide from, e.g., an oxygen-bearing gas (or plasma). Etch stop layer 60 is not limited to CVD deposited oxide and may include any material dissimilar to polysilicon. Etch stop layer 60 may, e.g., be 50 to 100 Å thick. FIG. 13 illustrates the deposition of a second polysilicon layer 62 across etch stop layer 60.

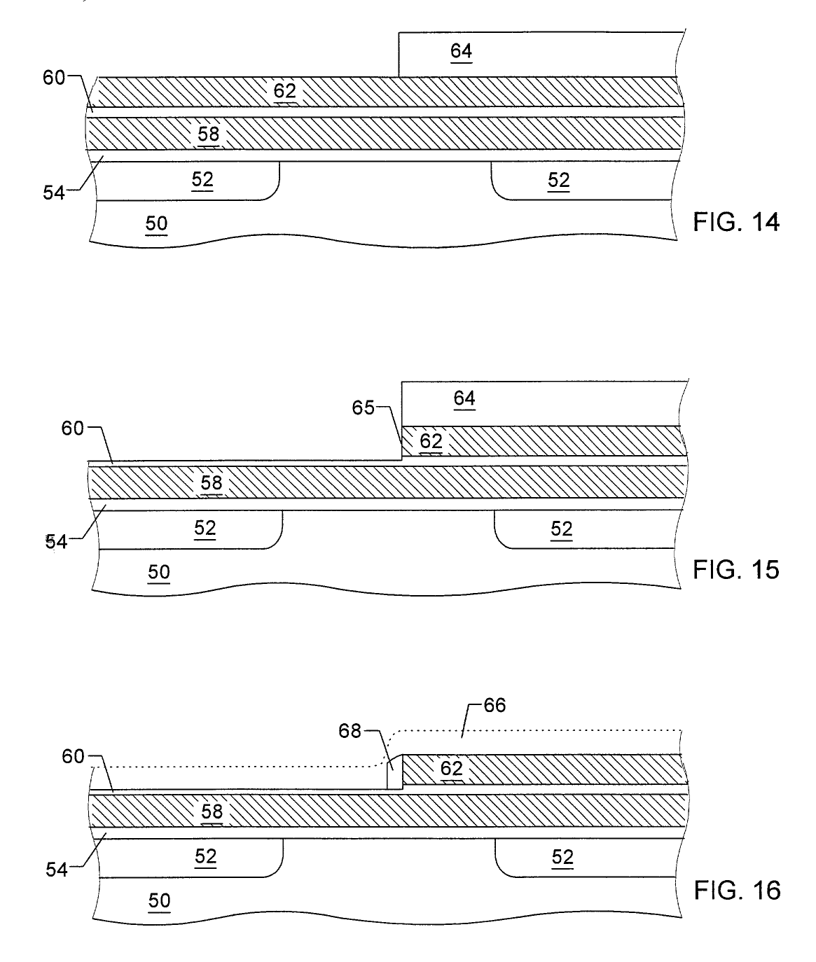

Turning to FIG. 14, a sacrificial layer 64 is formed across a select portion of second polysilicon layer 62. Sacrificial layer 64 preferably comprises photoresist patterned using lithography. It is to be understood that sacrificial layer 64 is not limited to photoresist and may be any material dissimilar to polysilicon. As shown in FIG. 15, an exposed portion of second polysilicon layer 62 may then be etched to etch stop layer 60 using an etch technique which exhibits a high selectivity to polysilicon as compared to etch stop layer 60. Although it may be difficult to terminate the etch duration precisely after the unmasked portion of second polysilicon layer 62 is completely removed, the presence of etch stop layer 60 inhibits the removal of first polysilicon layer 62. The etch rate significantly slows down upon reaching etch stop layer 60. While a small portion of etch stop layer 60 may be removed, the etch duration is terminated before the etch stop layer can be completely removed from first polysilicon layer 58. In this manner, a sidewall surface 65 is defined for second polysilicon layer 58.

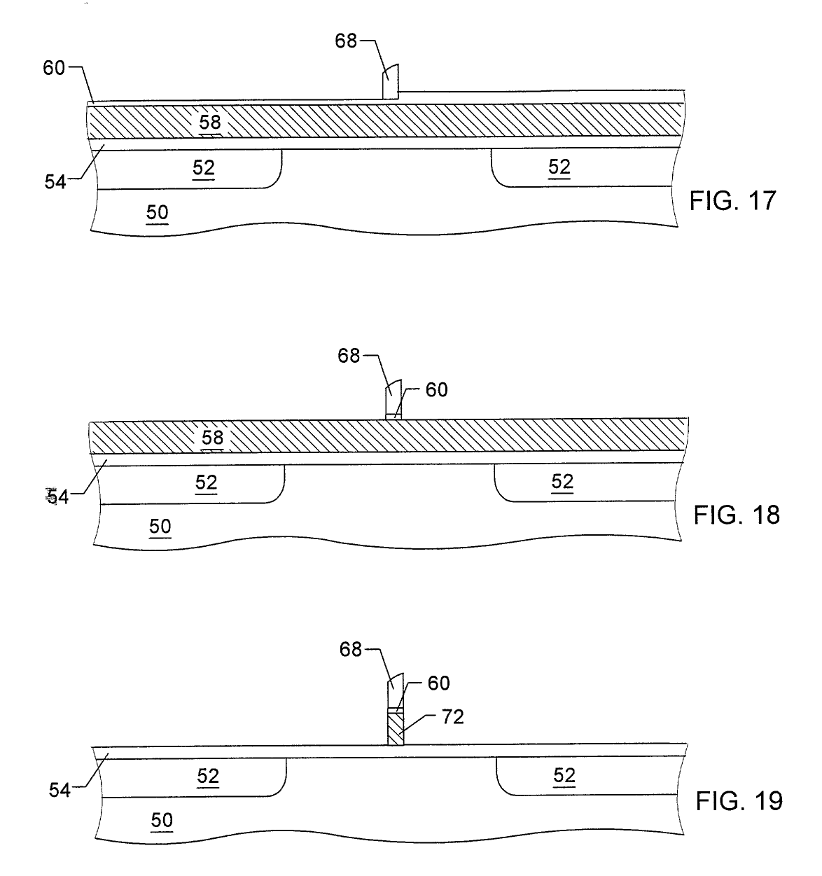

Subsequently, sacrificial layer 64 may be removed and a sidewall spacer 68 may be formed upon the sidewall surface of second polysilicon layer 62, as shown in FIG. 16. Sidewall spacer 68 is formed by depositing a spacer material which is substantially dissimilar to polysilicon and etch stop layer 60 across exposed surfaces of etch stop layer 60 and second polysilicon layer 62. The spacer material may, e.g., be silicon nitride or a metal. A portion 66 of the spacer material is then removed by anisotropically etching the spacer material. The duration of the anisotropic etch is chosen to terminate after only a pre-defined lateral thickness of spacer material (i.e., sidewall spacer 68) remains upon the sidewall surface of second polysilicon layer 62. Sidewall spacer 68 may, e.g., be about 50 to 200 Å thick. Turning to FIG. 17, first polysilicon layer 62 is then etched away using, e.g., an anisotropic etch technique that is highly selective to polysilicon as compared to the spacer material and the etch stop layer material. While a small portion of etch stop layer 60 may be etched, that portion is insignificant. As depicted in FIG. 18, portions of etch stop layer 60 not covered by sidewall spacer 68 may then be etched to first polysilicon layer 58 using an etch technique which exhibits a high selectivity to the etch stop layer material relative to the spacer material. FIG. 19 depicts the formation of a gate conductor 72 directly below spacer 60. A polysilicon gate conductor 72 may be formed by etching portions of first polysilicon layer 72 not covered by sidewall spacer 68 using an etch technique that is highly selective to polysilicon relative to the spacer material.

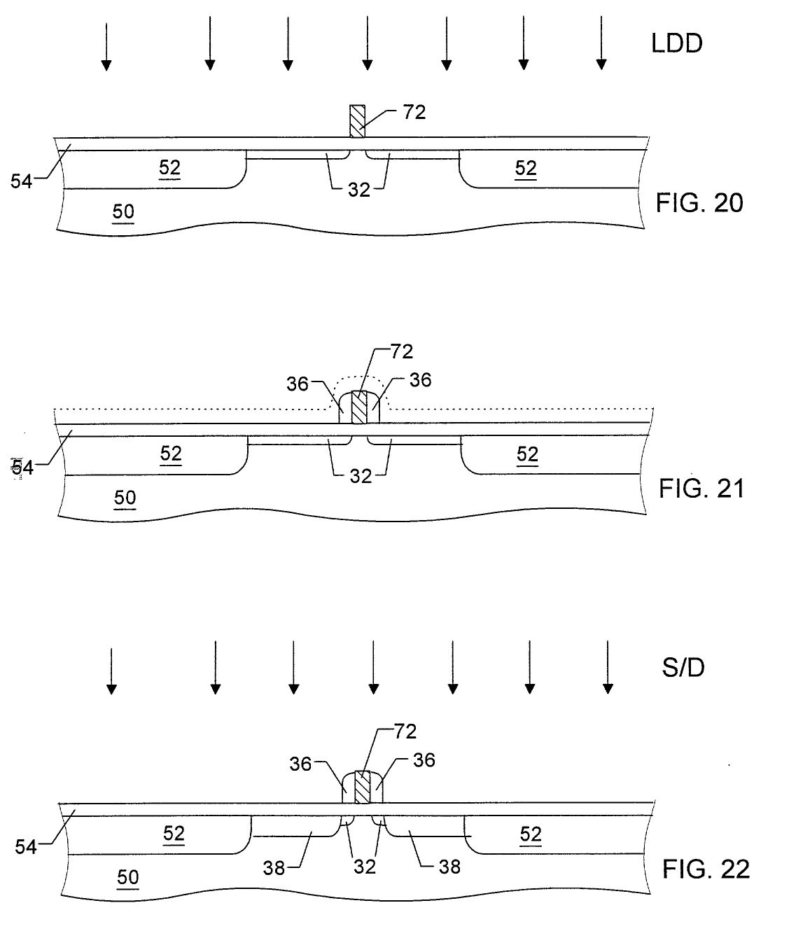

Turning to FIG. 20, relatively shallow LDD areas may be formed within substrate 32 using an LDD implant self-aligned to the opposed sidewall surfaces of gate conductor 72. Sidewall spacer 68 and etch stop layer 60 may be selectively etched from above gate conductor 72 prior to or after the LDD implant. FIG. 21 depicts the formation of dielectric spacers 36 upon the opposed sidewall surfaces of gate conductor 72. Spacers 36 are formed by CVD depositing a dielectric material, e.g., oxide, across the semiconductor topography, followed by anisotropically etching the dielectric material. As shown in FIG. 22, heavily doped source/drain regions 38 may be formed within substrate 38 a spaced distance from gate conductor 72 using a source/drain implant. The source/drain implant is performed at a higher dose and energy than the LDD implant and is self-aligned to the exposed lateral surfaces of dielectric spacers 36. As a result of the source/drain implant, LDD areas 32 only dominate regions of substrate 10 underneath dielectric spacers 36.

It will be appreciated to those skilled in the art having the benefit of this disclosure that this invention is believed to provide a method for forming a transistor having an ultra short channel length dictated by the width of a sacrificial sidewall spacer formed upon a sidewall surface of an etched polysilicon layer. Further modifications and alternative embodiments of various aspects of the invention will be apparent to those skilled in the art in view of this description. It is intended that the following claims be interpreted to embrace all such modifications and changes and, accordingly, the specification and drawings are to be regarded in an illustrative rather than a restrictive sense.

What is claimed is:

1. A method for forming an integrated circuit, comprising:
patterning a sacrificial layer upon a select portion of a polysilicon layer, wherein the polysilicon layer is spaced above a semiconductor substrate by a gate dielectric;
etching an exposed portion of the polysilicon layer to a level spaced below an upper surface of the select portion, thereby defining a sidewall surface of the polysilicon layer;
removing the sacrificial layer from the select portion of the polysilicon layer;
forming a sidewall spacer upon the sidewall surface of the polysilicon layer; and
etching portions of the polysilicon layer exclusive of underneath the sidewall spacer to form a polysilicon gate conductor.

2. The method of claim 1, wherein the gate dielectric is a thermally grown oxide.

3. The method of claim 1, wherein said forming the sidewall spacer comprises:
depositing a spacer material across the polysilicon layer; and
anisotropically etching the spacer material to remove the spacer material from horizontally oriented surfaces while retaining the spacer material upon the sidewall surface of the polysilicon layer.

4. The method of claim 3, wherein the spacer material comprises a material which is substantially dissimilar from polysilicon.

5. The method of claim 3, wherein the spacer material comprises a material selected from the group consisting of silicon dioxide, silicon nitride, and silicon oxynitride.

6. The method of claim 1, wherein the sacrificial material comprises photoresist patterned using optical lithography.

7. The method of claim 1, wherein said etching the exposed portion of the polysilicon layer comprises removing approximately ⅓ to ½ of the thickness of the exposed portion.

8. The method of claim 1, wherein an etch stop layer extends horizontally through the polysilicon layer, and wherein the etch stop layer partitions the polysilicon layer into an upper portion and a lower portion.

9. The method of claim 8, wherein the etch stop layer comprises a material substantially dissimilar from polysilicon.

10. The method of claim 8, wherein the etch stop layer comprises silicon dioxide.

11. The method of claim 8, wherein said etching the exposed portion of the polysilicon layer comprises etching the exposed portion to the etch stop layer.

12. The method of claim 11, wherein the etch stop layer substantially inhibits removal of the lower portion of the polysilicon layer during said etching the exposed portion.

13. The method of claim 8, wherein the sidewall spacer comprises a material substantially dissimilar from polysilicon and the etch stop layer.

14. The method of claim 1, wherein said etching the portions of the polysilicon layer comprises anisotropically and selectively etching the portions.

15. The method of claim 8, further comprising anisotropically etching select portions of the etch stop layer concurrent with said etching the portions of the polysilicon layer.

16. The method of claim 1, further comprising:
removing the sidewall spacer from above the gate conductor; and
implanting a lightly doped drain implant which is self-aligned to opposed sidewall surfaces of the gate conductor into the substrate to form lightly doped drain areas.

17. The method of claim 16, further comprising:
forming a pair of spacer structures upon the opposed sidewall surfaces of the gate conductor; and
implanting a source/drain implant which is self-aligned to exposed lateral surfaces of the pair of sidewall spacers into the substrate to form source and drain regions.

18. The method of claim 1, wherein the gate conductor comprises a lateral width of approximately 50 to 200 Å.

19. An integrated circuit comprising:
a gate conductor spaced above a semiconductor substrate by a gate dielectric, the gate conductor having been patterned from a lower portion of a polysilicon layer arranged underneath a pre-existing sidewall spacer, the sidewall spacer having been formed upon a sidewall surface of an upper portion of the polysilicon layer.

20. The integrated circuit of claim 19, wherein the gate conductor comprises a lateral width of approximately 50 to 200 Å.

21. The integrated circuit of claim 19, further comprising a pair of sidewall spacers arranged upon opposed sidewall surfaces of the gate conductor.

22. The integrated circuit of claim 19, wherein the gate conductor comprises doped polysilicon.

23. The integrated circuit of claim 19, further comprising lightly doped drain areas arranged within the semiconductor substrate directly underneath the sidewall spacers laterally adjacent the opposed sidewall surfaces of the gate conductor.

24. The integrated circuit of claim 19, further comprising source and drain regions arranged within the semiconductor substrate laterally adjacent the lightly doped drain areas.

25. The integrated circuit of claim 24, wherein the source and drain regions are spaced laterally from the opposed sidewall surfaces of the gate conductor by a distance substantially equivalent to a thickness of each of the pair of sidewall spacers.
